(19) United States
(12) Patent Application Publication
(10) Pub. No.: US 2025/0140514 A1
(43) Pub. Date: May 1, 2025

(54) Liquid cells for the study of electrochemical processes using transmission electron microscopy

(71) Applicant: The Regents of the University of California, Oakland, CA (US)

(72) Inventors: Haimei Zheng, Berkeley, CA (US); Sophia Betzler, Berkeley, CA (US); Jiawei Wan, Albany, CA (US); Qiubo Zhang, Albany, CA (US); Xianhu Sun, EL Cerrito, CA (US)

(21) Appl. No.: 18/917,129

(22) Filed: Oct. 16, 2024

Related U.S. Application Data
(60) Provisional application No. 63/593,602, filed on Oct. 27, 2023.

(51) Int. Cl. H01J 37/20; H01J 37/26

(52) U.S. Cl. CPC H01J 37/20; H01J 37/26

(57) ABSTRACT

This disclosure provides systems, methods, and apparatus related to liquid cells for use in transmission electron microscopy (TEM). In one aspect, as assembly includes a first TEM element and a second TEM element. The first TEM element comprises a grid with a first oxide disposed thereon, a first polymer layer disposed on the first oxide, and a first electrode and a second electrode disposed on the first polymer layer. The second TEM element comprises a second grid having a second oxide disposed thereon and a second polymer layer disposed on the second oxide. The second TEM element has a circular shape with a portion of the circular shape being removed such that an end of the first electrode and an end of the second electrode are exposed when the second TEM element is placed on top of the first TEM element to form the assembly.

### RELATED APPLICATIONS

This application claims priority to U.S. Provisional Patent Application No. 63/593,602, filed Oct. 27, 2023, which is herein incorporated by reference.

### STATEMENT OF GOVERNMENT SUPPORT

This invention was made with government support under Contract No. DE-AC02- 05CH11231 awarded by the U.S. Department of Energy. The government has certain rights in this invention.

### TECHNICAL FIELD

This disclosure relates generally to liquid cells for the study of electrochemical processes using transmission electron microscopy (TEM).

### BACKGROUND

A growing interest in the field of transmission electron microscopy (TEM) are liquid cell experiments which allow the direct observation of chemical reactions, providing valuable insights into underlying mechanisms. These experiments use electron transparent cells to encapsulate the liquid. Next to reactions introduced by the electron beam external stimuli, the intermixing of liquids or biasing, both of which can initiate chemical reactions, are important. Experiments with the intermixing of liquids or biasing require more complex cell designs.

Additionally, conventional cell designs suffer from large cell thicknesses required to incorporate the electrodes which dramatically reduces the achievable spatial resolution.

### SUMMARY

One innovative aspect of the subject matter described in this disclosure can be implemented in an assembly including a first transition electron microscopy (TEM) element and a second TEM element. The first TEM element comprises a first grid with a first oxide disposed on a first side of the first grid, a first polymer layer disposed on the first oxide, and a first electrode and a second electrode disposed on the first polymer layer. The first TEM element has a first circular shape. The second TEM element comprises a second grid having a second oxide disposed on a first side of the second grid, and a second polymer layer disposed on the second oxide. The second TEM element has a second circular shape with a portion of the second circular shape being removed such that an end of the first electrode and an end of the second electrode are exposed when the second TEM element is placed on top of the first TEM element to form the assembly.

Another innovative aspect of the subject matter described in this disclosure can be implemented in an assembly including a first transition electron microscopy (TEM) element and a second TEM element. The first TEM element comprises a first grid, a first oxide disposed on a first side of the first grid, a first polymer layer disposed on the first oxide, and a first electrode and a second electrode disposed on the first polymer layer. The first TEM grid has a first circular shape. The second TEM element comprises a second grid having a second oxide disposed on a first side of the second grid, and a second polymer layer disposed on the second oxide, the second TEM element having a second circular shape with a flat side such that an end of the first electrode and an end of the second electrode are exposed when the second TEM element is placed on top of the first TEM element to form the assembly.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1A and 1B show examples of schematic illustrations an electron microscopy grid.

FIGS. 2A-2C show examples of schematic illustrations of a first TEM element and a second TEM element forming an TEM grid assembly.

FIG. 3 shows an example of a schematic illustration of a first TEM element with not including electrodes.

FIGS. 4A and 4B show examples of schematic illustration of the electrodes disposed on a first polymer layer of a first TEM element.

FIG. 5 shows an example of a photograph of a TEM sample holder.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

An electron microscopy grid is a grid upon which a sample to be observed in an electron microscope can be placed. The electron microscopy grid can be placed in an electron microscopy specimen holder that can be inserted into the electron microscope. Electron microscopy grids are generally used in transmission electron microscopy (TEM).

An electron microscopy grid can be made of a number of materials or a combination or alloy of such materials. In some embodiments, the electron microscopy grid comprises gold, molybdenum, titanium, or copper. An electron microscopy grid is generally an about 3.05 millimeter (mm) diameter disc that has a thickness and mesh size ranging from about 3 microns to 100 microns. In some embodiments, an electron microscopy grid has a thickness of about 30 microns and a mesh size of about 100 microns.

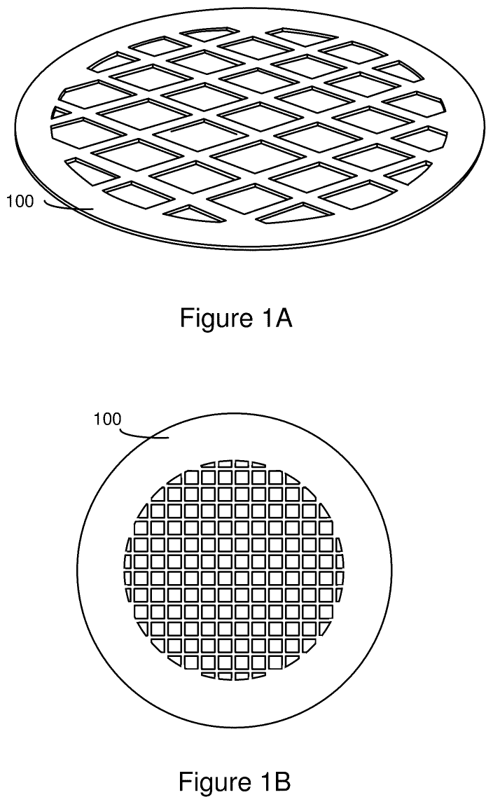

FIGS. 1A and 1B show examples of schematic illustrations an electron microscopy grid. FIG. 1A shows a view of an electron microscopy grid 100. FIG. 1B shows a top-down view of the electron microscopy grid 100. The electron microscopy grid 100 shown in FIGS. 1A and 1B is also referred to herein as a TEM grid or a grid.

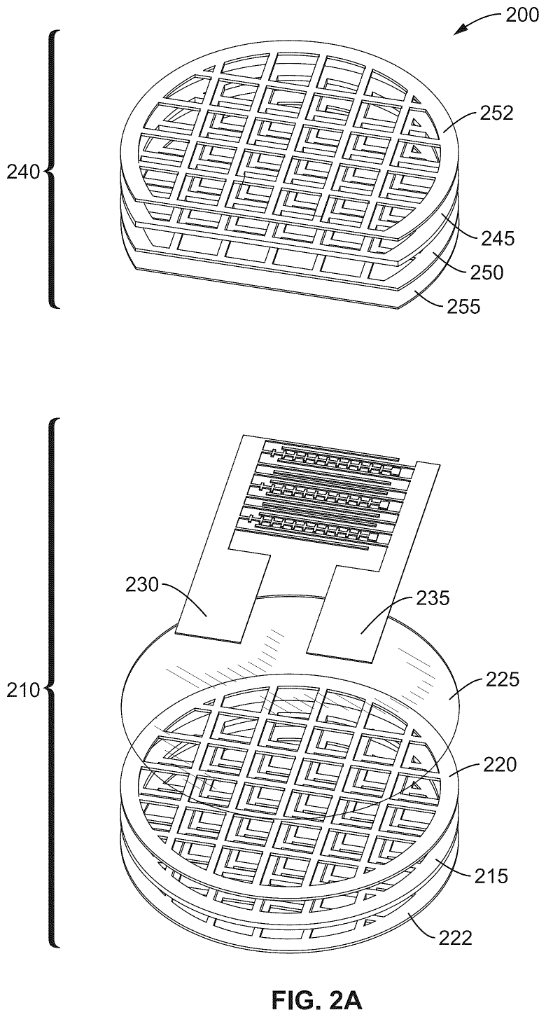

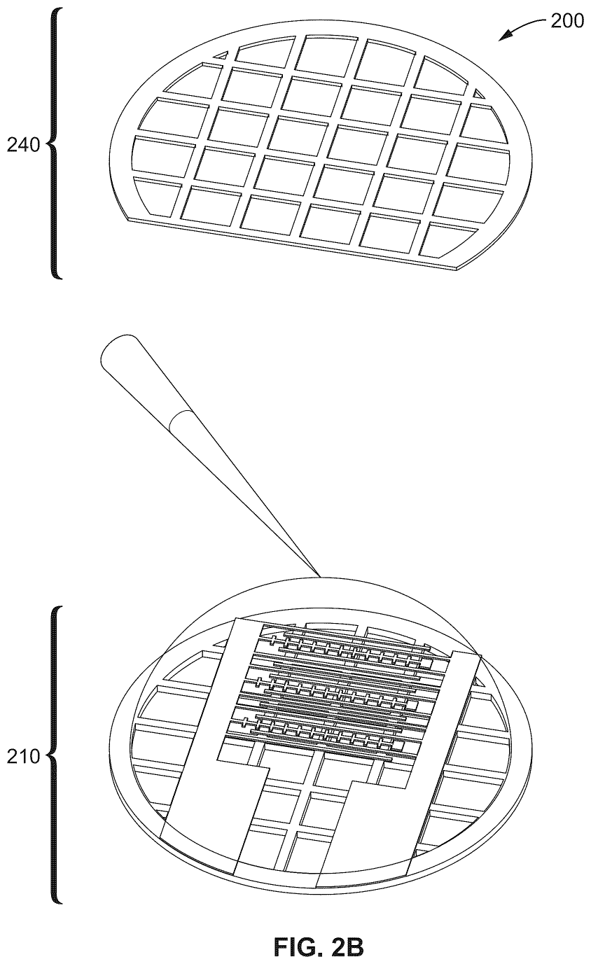

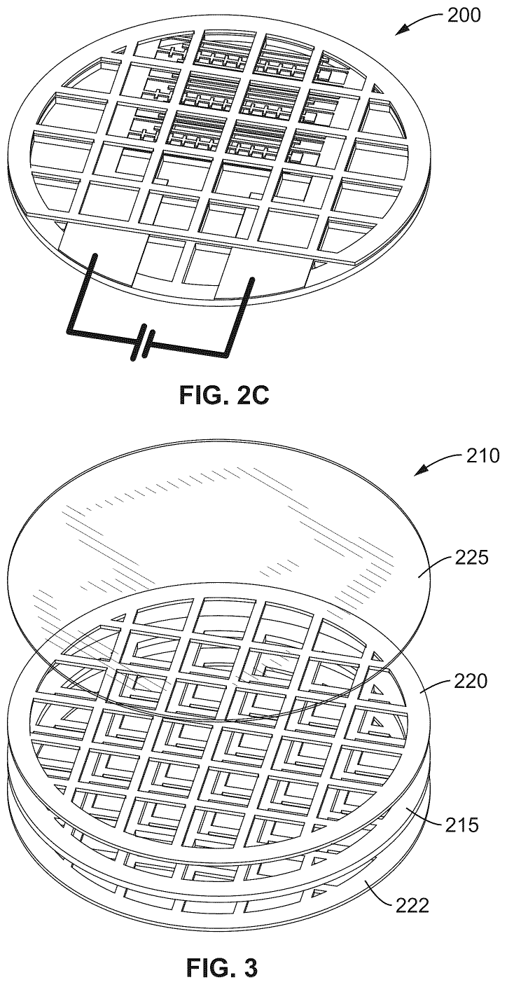

FIGS. 2A-2C show examples of schematic illustrations of a first TEM element and a second TEM element forming an TEM grid assembly. FIG. 3 shows an example of a schematic illustration of a first TEM element not including electrodes.

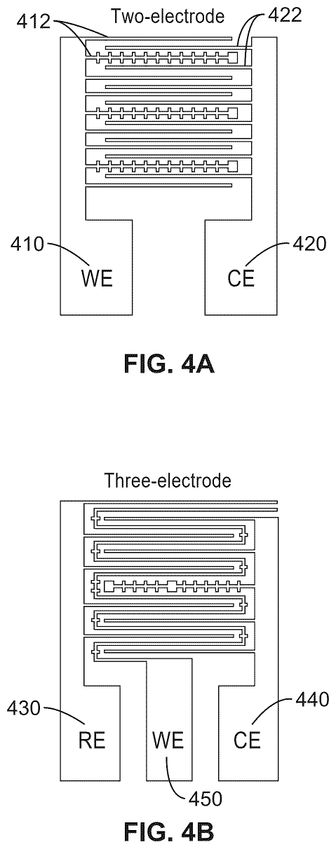

Starting at FIG. 2A, a TEM grid assembly 200 (also referred to herein as an assembly) includes a first TEM element 210 and a second TEM element 240. The first TEM element 210 comprises a first grid 215. The first grid 215 may comprises any of the electron microscopy grids described with respect to FIGS. 1A and 1B. The first grid 215 has a first oxide 220 disposed on a first side of the first grid 215. A first polymer layer 225 is disposed on the first oxide 220. A first electrode 230 and a second electrode 235 are disposed on the first polymer layer 225. The electrodes are described further below with respect to FIGS. 4A and 4B. In some embodiments, the first TEM element 210 has a first circular shape.

In some embodiments, a third oxide 222 is disposed on a second side of the first grid 215. In some embodiments, the third oxide is the same oxide as the first oxide. In some embodiments, the third oxide 222 provides electrical insulation of the TEM grid assembly 200 from the TEM sample holder (i.e., when the TEM sample holder includes metal that would be in contact with the flat perimeter of the first TEM element 210).

The second TEM element 240 is similar to the first TEM element 210. The second TEM element 240 comprises a second grid 245. The second grid 245 may comprises any of the electron microscopy grids described with respect to FIGS. 1A and 1B. The second grid 245 has a second oxide 250 disposed on a first side of the second grid 245. A second polymer layer 255 is disposed on the second oxide 250. In some embodiments, the second TEM element has a second circular shape with a portion of the second circular shape being removed such that an end of the first electrode and an end of the second electrode are exposed when the second TEM element 240 is placed on top of the first TEM element 210 to form the assembly 200. In some embodiments, the second circular shape with a portion of the second circular shape being removed is a circular shape with a flat portion. In some embodiments, the assembly 200 has a circular shape. In some embodiments, the first polymer film is proximate the second polymer film when the second TEM element is placed on top of the first TEM element.

In some embodiments, a fourth oxide 252 is disposed on a second side of the second grid 245. In some embodiments, the fourth oxide 252 is the same oxide as the second oxide. In some embodiments, the fourth oxide 222 provides electrical insulation of the TEM grid assembly 200 from the TEM sample holder (i.e., when the TEM sample holder includes metal that would be in contact with the flat perimeter of the second TEM element 240).

In some embodiments, a diameter of the first TEM element and the second TEM element is about 3 millimeters.

In some embodiments, the first grid 215 and the second grid 245 comprise copper grids. In some embodiments, the first grid 215 and the second grid 245 comprise 200 mesh grids. In some embodiments, the first grid 215 and the second grid 245 are about 3 mm grids.

In some embodiments, the first oxide and the second oxide comprise non-electrically conductive oxides. In some embodiments, the first oxide and the second oxide comprise alumina, silicon oxide, or titanium oxide. In some embodiments, the first oxide and the second oxide are about 250 nanometers to 750 nanometers thick, or about 500 nanometers thick.

In some embodiments, the first polymer layer and the second polymer layer comprise polyvinyl formal or polyimide. In some embodiments, the first polymer layer and the second polymer layer are about 5 nanometers to 50 nanometers thick, or about 10 nanometers to 15 nanometers thick, or about 10 nanometers thick. In some embodiments, the first polymer layer and the second polymer layer are impermeable to liquids.

In some embodiments, when the assembly is in use (e.g., in a TEM), a liquid is disposed between the first polymer layer and the second polymer layer of the assembly. In some embodiments, the liquid has a thickness of about 20 nanometers to 100 nanometers.

FIG. 2B shows an example of schematic illustration of a sample or an electrolyte deposited on a first TEM element using a pipette. FIG. 2C shows an example of a schematic illustration a TEM grid assembly including a sample or an electrolyte disposed between a first TEM element and a second TEM element.

FIGS. 4A and 4B show examples of schematic illustration of the electrodes disposed on a first polymer layer of a first TEM element. Starting with FIG. 4A, the electrodes disposed on the first polymer layer of the first TEM element the electrodes include a first electrode 410 and a second electrode 420. In some embodiments, the first electrode 410 is a working electrode and the second electrode 420 is a counter electrode. In some embodiments, the first electrode 410 includes first arms 412. In some embodiments, the second electrode 420 includes second arms 422. In some embodiments, the first arms 412 are interdigitated with the second arms 422.

To further clarify the relation of the first arms 412 with the second arms 422 in some embodiments, a definition of interdigitate is “to become interlocked like the fingers of folded hands.” While the first arms 412 with the second arms 422 are not physically interlocked or physically in contact with one another, they are arranged such that the arms alternate first arm, second arm, first arm, second arm, and so on.

In some embodiments, the first electrode 410 and the second electrode 420 comprise platinum, gold, titanium, or carbon (e.g., amorphous carbon or graphene). In some embodiments, the first electrode 410 and the second electrode 420 are about 1 nanometer to 15 nanometers thick, or about 10 nanometers thick.

Turning to FIG. 4B, in some embodiments, a first TEM element further includes a third electrode disposed on the first polymer layer. As with the first electrode and the second electrode, an end of the third electrode is exposed when the second TEM element is placed on top of the first TEM element to form the assembly.

As shown in FIG. 4B, the electrodes disposed on the polymer layer of a first TEM element include a first electrode 430, a second electrode 440, and a third electrode 450. In some embodiments, the first electrode 430 is a reference electrode, the second electrode 440 is a counter electrode, and the third electrode 450 is a working electrode.

In some embodiments, the third electrode 450 is disposed on the first polymer later in a sinuous pattern. In some embodiments, the first electrode 430 includes first arms. In some embodiments, the second electrode 440 includes second arms. The first arms are interdigitated with the third electrode 450 on a first side of the third electrode 450. The second arms are interdigitated with the third electrode 450 on a second side of the third electrode 450.

In some embodiments, the first electrode, the second electrode, and the third electrode comprise platinum, gold, titanium, or carbon (e.g., amorphous carbon or graphene).

In some embodiments, the first electrode, the second electrode, and the third electrode are about 1 nanometer to 15 nanometers thick, or about 10 nanometers thick.

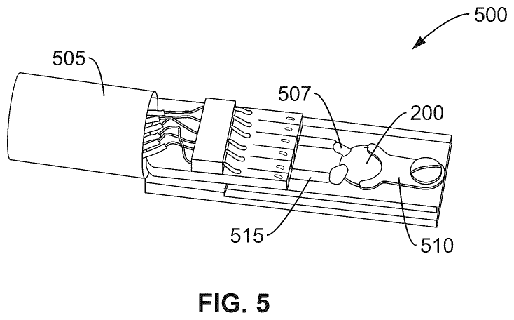

FIG. 5 shows an example of a photograph of a TEM sample holder. As shown in FIG. 5, a TEM sample holder 500 includes a rod 505 with a cutout to hold any of the TEM element assemblies described herein. The TEM sample holder 500 further includes a clamp 510 (e.g., a copper clamp) to hold a TEM grid assembly 200 in the cutout. In some embodiments, the clamp 510 is used to stabilize and hold the TEM grid assembly 200 in place and prevent it from falling off into the column of a TEM. Contacts 515 (e.g., gold contacts) disposed on the rod 505 provide electrical contact to the TEM grid assembly 200. In some embodiments, silver conducting paste 507 is used to provide electrical contact between the contacts 515 and the electrodes of a TEM grid assembly 200.

A manufacturing process for the TEM grid assembly includes providing TEM grids. In some embodiments, an oxide layer is deposited on an TEM grid using sputtering, e-beam evaporation, or an ALD/CVD process. In some embodiments, a polymer layer is deposited on the oxide layer using a spin coating process. In some embodiments, electrodes are formed on the polymer layer of the first TEM element using a shadow mask and a deposition process such as sputtering, e-beam evaporation, or an ALD/CVD process.

In some embodiments, to use the TEM grid assembly for an experiment, a sample is drop-cast onto the TEM element that includes the electrodes (i.e., the first TEM element). A droplet of the electrolyte of interest is deposited onto the first TEM element, which is subsequently covered by the second TEM element to form the TEM grid assembly. The liquid is confined between the two TEM elements due to van der Waals forces which pull the two TEM elements together and seal the liquid between the two TEM elements.

The following examples are intended to be examples of the embodiments disclosed herein, and are not intended to be limiting.

### Example—Fabrication of High-Resolution Electrochemical Liquid Cell for In-Situ TEM

An electrochemical TEM liquid cell was fabricated using commercial copper TEM grids (200 square mesh). The top copper grid was trimmed on one edge (0.5 mm to 1 mm width) with a razor blade to facilitate electrode contact with a TEM biasing holder. Both the top and bottom grids were coated with a 500 nm layer of electrically insulating aluminum oxide by sputter deposition to prevent electric shorting. Subsequently, a 10 nm-thick Formvar polymer film was transferred onto the TEM grids. To achieve this, glass slides were immersed in a 0.25% Formvar solution in 1, 2-dichloroethane with films on their surface and then transferred into the water, where the surface tension of water helped to separate the Formvar films from the glass slides and float on the water. The top and bottom grids were then placed onto the film with their aluminum oxide-coated side facing downwards and removed from the water. Lastly, 10 nm-thick platinum interdigital electrodes were deposited onto the bottom grids using e-beam evaporation through a shadow mask. The distance between the two closest electrodes was 0.035 mm, allowing for the control of electric biasing within the liquid cell.

### Example—Fluctuating Amorphous Interphase at Electrified Solid-Liquid Interfaces (ESLIs)

As an example of the types of experiments that can be conducted using the TEM grid assemblies described herein, we conducted Cu-catalysed CO₂ER experiments. One TEM imaged showed a single electrolyte pocket within the TEM grid assembly in which a Cu nanowire was connected to the Pt cathode, as confirmed by the high-angle annular dark-field (HAADF). The redox potential and current-potential curves measured through the TEM grid assembly indicated that the TEM grid assembly functioned well. We monitored the interfaces between the Cu catalyst and electrolyte under electrochemical conditions in the TEM grid assembly. Following the applied potential, a fluctuating liquid-like amorphous structure was observed on the Cu nanowire surface. It fluctuated with cyclic disappearance and occurrence. The interface between the amorphous interphase and the electrolyte seems smooth, whereas the interface with the crystalline Cu is rough, with atomic steps.

Our control experiments showed that, under identical electron-beam irradiation conditions, without biasing, there is no such amorphous interphase. Furthermore, ex situ H-cell electrochemical experiments also verified the formed amorphous at the surface of Cu nanowires after electrochemical activation. Ex situ flow-cell experiments revealed that Cu catalyst exhibited a stepped surface post-CO₂ER testing, which is reminiscent of that observed in H cells, implying similar reconstruction of catalyst surfaces, therefore the generation of amorphous structures at the ESLI is intrinsic under electrochemical conditions. By contrast, electron-beam irradiation promotes crystallization of the amorphous interphase to form Cu(OH)₂ and Cu₂O nanocrystals, which further excludes electron-beam-induced amorphization.

As well as the structure information, a TEM grid assembly allows for rapid cooling to the cryogenic temperature to freeze the activated amorphous interphase, indicating diverse applications the TEM grid assembly. Energy-dispersive X-ray spectroscopy (EDS) and electron energy loss spectroscopy (EELS) of the frozen amorphous interphase enabled composition and valence states analysis. Our control experiments with high-resolution transmission electron microscopy (HRTEM) imaging indicated that the amorphous interphase comprises Cu, O and H. This is attributed to the fact that the elements present in the formed nanocrystals can only originate from the amorphous interphase layer. The EDS spectra further confirmed the presence of Cu in the amorphous interphase. Furthermore, by comparing the C-to-O ratio in the amorphous layer and the crystalline Cu segment, we also found the presence of C in the amorphous layer.

Therefore, we summarize that Cu, C, H and O have been identified in the amorphous interphase. EELS spectra showed that the amorphous interphase contains both Cu⁰ and Cu¹⁺. Using the multiple linear least squares fitting method, we estimated the ratio of Cu⁰ to Cu¹⁺ and the results indicate that the ratio of Cu⁰ to Cu¹⁺ increases when the position is closer to the amorphous-crystalline Cu interface. On the basis of the above chemical analysis, we can conclude that the amorphous interphase is a complex containing Cu⁰ and Cu¹⁺.

### CONCLUSION

Further details regarding the embodiments described herein can be found in Zhang, Q., Song, Z., Sun, X. et al. “Atomic dynamics of electrified solid-liquid interfaces in liquid-cell TEM,” Nature 630, 643-647 (2024), which is hereby incorporated by reference.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. An assembly comprising:
a first transition electron microscopy (TEM) element comprising a first grid, a first oxide disposed on a first side of the first grid, a first polymer layer disposed on the first oxide, and a first electrode and a second electrode disposed on the first polymer layer, the first TEM element having a first circular shape;
a second TEM element comprising a second grid having a second oxide disposed on a first side of the second grid, and a second polymer layer disposed on the second oxide, the second TEM element having a second circular shape with a portion of the second circular shape being removed such that an end of the first electrode and an end of the second electrode are exposed when the second TEM element is placed on top of the first TEM element to form the assembly.

2. The assembly of claim 1, wherein the first electrode is a working electrode and the second electrode is a counter electrode.

3. The assembly of claim 2, wherein the first electrode includes first arms, wherein the second electrode includes second arms, and wherein the first arms are interdigitated with the second arms.

4. The assembly of claim 1, wherein the first electrode and the second electrode comprise platinum, gold, titanium, or carbon.

5. The assembly of claim 1, wherein the first electrode and the second electrode are about 1 nanometer to 15 nanometers thick.

6. The assembly of claim 1, wherein the first TEM element further includes a third electrode disposed on the first polymer layer, and wherein an end of the third electrode is exposed when the second TEM element is placed on top of the first TEM element to form the assembly.

7. The assembly of claim 6, wherein the first electrode is a reference electrode, wherein the second electrode is a counter electrode, and wherein the third electrode is a working electrode.

8. The assembly of claim 6, wherein the third electrode is disposed on the first polymer later in a sinuous pattern, wherein the first electrode includes first arms, wherein the second electrode includes second arms, wherein the first arms are interdigitated with the third electrode on a first side of the third electrode, and wherein the second arms are interdigitated with the third electrode on a second side of the third electrode.

9. The assembly of claim 6, wherein the first electrode, the second electrode, and the third electrode comprise platinum, gold, titanium, or carbon.

10. The assembly of claim 1, wherein the second circular shape with a portion of the second circular shape being removed is a circular shape with a flat portion.

11. The assembly of claim 1, wherein the first polymer film is proximate the second polymer film when the second TEM element is placed on top of the first TEM element.

12. The assembly of claim 1, wherein the first grid and the second grid comprise copper grids.

13. The assembly of claim 1, wherein the first oxide and the second oxide comprise non-electrically conductive oxides.

14. The assembly of claim 1, wherein the first oxide and the second oxide comprise alumina, silicon oxide, or titanium oxide.

15. The assembly of claim 1, wherein the first polymer layer and the second polymer layer comprise polyvinyl formal or polyimide.

16. The assembly of claim 1, wherein a diameter of the first TEM element and the second TEM element are about 3 millimeters.

17. The assembly of claim 1, wherein when in operation, a liquid is disposed between the first polymer layer and the second polymer layer of the assembly.

18. The assembly of claim 1, wherein when in operation, a liquid is disposed between the first polymer layer and the second polymer layer of the assembly, and wherein the liquid has a thickness of about 20 nanometers to 100 nanometers.

19. The assembly of claim 1, wherein the first polymer layer and the second polymer layer are impermeable to liquids.

20. An assembly comprising:
a first transition electron microscopy (TEM) element comprising a first grid, a first oxide disposed on a first side of the first grid, a first polymer layer disposed on the first oxide, and a first electrode and a second electrode disposed on the first polymer layer, the first TEM element having a first circular shape;
a second TEM element comprising a second grid having a second oxide disposed on a first side of the second grid, and a second polymer layer disposed on the second oxide, the second TEM element having a second circular shape with a flat side such that an end of the first electrode and an end of the second electrode are exposed when the second TEM element is placed on top of the first TEM element to form the assembly.
